(19) United States
(12) Patent Application Publication
(10) Pub. No.: US 2026/0182417 A1
(43) Pub. Date: Jun. 25, 2026

(54) MONOLOTHIC MICROWAVE INTEGRATED CIRCUIT WITH THERMALLY CONDUCTIVE POCKETED INTERPOSER

(71) Applicant: Qorvo US, Inc., Greensboro, NC (US)

(72) Inventors: Tarak A. Railkar, Carrollton, TX (US); Lidia C. El Bouanani, Greensboro, NC (US); Jeffrey M. Miller, Allen, TX (US)

(21) Appl. No.: 19/375,793

(22) Filed: Oct. 31, 2025

Related U.S. Application Data
(60) Provisional application No. 63/738,145, filed on Dec. 23, 2024.
(60) Provisional application No. 63/762,387, filed on Feb. 24, 2025.

(51) Int. Cl. H01L 23/498; H01L 23/00; H01L 23/36; H01L 23/48

(52) U.S. Cl. CPC H10W 70/65; H10W 20/20; H10W 40/10; H10W 72/884; H10W 90/734; H10W 90/754

(57) ABSTRACT

A monolithic microwave integrated circuit (MMIC) device includes a MMIC die comprising, which includes an active circuit layer, a first substrate material, at least one conductive through-semiconductor via (TSV) extending completely through the first substrate material from a top side to a bottom side of the MMIC die. The MMIC device also includes a thermally conductive interposer which includes: a second substrate material different from the first substrate material and electrically insulating at an operating voltage of the MMIC die, at least one conductive via, pad, or trace in electrical contact with the at least one conductive TSV or the active circuit layer, and a pocket configured to receive the MMIC die.

### CROSS REFERENCE TO RELATED APPLICATIONS

This application claims the priority benefit of U.S. Provisional Patent Application No. 63/762,387, filed Feb. 24, 2025, and U.S. Provisional Patent Application No. 63/738,145, filed Dec. 23, 2024, both of which are hereby expressly incorporated by reference in their entirety as though fully set forth herein.

### TECHNICAL FIELD

The subject matter described herein relates to a devices, systems, and methods for providing heat dissipation, electrical interconnects, and mechanical support to a monolithic microwave integrated circuit (MMIC). This MMIC with thermally conductive, pocketed interposer has particular but not exclusive utility for high-power radio frequency (RF) applications and phased-array antennas.

### BACKGROUND

A monolithic microwave integrated circuit (MMIC) chip may be referred to as a die, and may for example be fabricated with copper or gold traces on a silicon (Si), gallium arsenide (GaAs) or gallium nitride (GaN) wafer. In some cases, a MMIC die may be packaged in a durable housing or chip-scale package. However, in other cases, it may be desirable to supply a MMIC to an RF equipment manufacturer as a bare die. With a significant increase in the power handling levels of MMICs over the past several decades, it is sometimes desirable to mount the MMIC to a heat spreader, e.g., a mechanical support component that is electrically insulating (or a high-bandgap material) but thermally conducting, such that heat generated by the MMIC may be transmitted to all parts of the heat spreader and either dissipated into the environment or transferred to a heat sink or cooling system. Such a heat spreader may in some cases be referred to as a “tab”, and a bare MMIC die mounted to the heat spreader may be referred to as a “tabbed” MMIC.

The information included in this Background section of the specification, including any references cited herein and any description or discussion thereof, is included for technical reference purposes only and is not to be regarded as subject matter by which the scope of the disclosure is to be bound.

### SUMMARY

Disclosed is a monolithic microwave integrated circuit (MMIC) with thermally conductive, pocketed interposer which provides interconnect and fanout capability to a MMIC die, along with mechanical support, while dissipating heat generated by the MMIC die during operation. The MMIC die may include at least one conductive through-semiconductor via (TSV), and the thermally conductive interposer includes at least one conductive via, pad, or trace in electrical contact with the TSV or with the active circuit layer of the MMIC die. The thermally conductive interposer includes a pocket for retaining the MMIC die. The pocket may extend partway through the thermally conductive interposer, or may extend completely through the thermally conductive interposer from the top surface through to the bottom surface. The MMIC with thermally conductive, pocketed interposer disclosed herein has particular, but not exclusive, utility for high-power radio frequency systems and phased-array antennas.

One general aspect of the MMIC with thermally conductive, pocketed interposer includes a monolithic microwave integrated circuit (MMIC) device. The monolithic microwave integrated circuit includes a MMIC die that may include: an active circuit layer, a first substrate material, and at least one conductive through-semiconductor via (TSV) extending completely through the first substrate material from a top side to a bottom side of the MMIC die. The MMIC device also includes a thermally conductive interposer that may include: a second substrate material different from the first substrate material and electrically insulating at an operating voltage of the MMIC die; at least one conductive via, pad, or trace in electrical contact with the at least one conductive TSV or the active circuit layer; and a pocket configured to receive the MMIC die.

Implementations may include one or more of the following features. In some embodiments, the first substrate material is silicon, gallium arsenide, or gallium nitride or the second substrate material is silicon carbide, aluminum nitride, or diamond. In some embodiments, the MMIC device may include an electrically conductive fence at least partially surrounding the pocket on a surface of the thermally conductive interposer. In some embodiments, the second substrate material has a thermal conductivity of at least at least 200 W/mK or a fracture toughness of between 2.0 and 6.8 MPa m0.5. In some embodiments, the at least one conductive via, pad, or trace may include a routing layer or redistribution layer or a conductive via extending completely through the second substrate material from a top side to a bottom side of the thermally conductive interposer. In some embodiments, the pocket extends completely through the thermally conductive interposer from a top surface to a bottom surface. In some embodiments, the pocket extends only partially through the thermally conductive interposer. In some embodiments, the MMIC die is attached to the pocket by a thermally conductive adhesive.

One general aspect includes a method for packaging a monolithic microwave integrated circuit (MMIC). The method includes providing a MMIC die that may include: an active circuit layer, a first substrate material, at least one conductive through-semiconductor via (TSV) extending completely through the first substrate material from a top side to a bottom side of the MMIC die. The method also includes providing a thermally conductive interposer that may include: a second substrate material different from the first substrate material and electrically insulating at an operating voltage of the MMIC die, and at least one conductive via, pad, or trace; and a pocket configured to receive the MMIC die. The method also includes bonding the MMIC die to the thermally conductive interposer such that the at least one conductive via, pad, or trace is in electrical contact with the at least one conductive TSV or the active circuit layer.

Implementations may include one or more of the following features. In some embodiments, the first substrate material is silicon, gallium arsenide, or gallium nitride or the second substrate material is silicon carbide, aluminum nitride, or diamond. In some embodiments, the method may include providing an electrically conductive fence at least partially surrounding the pocket on a surface of the thermally conductive interposer. In some embodiments, the MMIC die is attached to the pocket by a thermally conductive adhesive. In some embodiments, the second substrate material has a thermal conductivity of at least at least 200 W/mK or the second substrate material has a fracture toughness of between 2.0 and 6.8 MPa m0.5. In some embodiments, the at least one conductive via, pad, or trace may include a routing layer or redistribution layer or a conductive via extending completely through the second substrate material from a top side to a bottom side of the thermally conductive interposer. In some embodiments, the pocket extends completely through the thermally conductive interposer from a top surface to a bottom surface. In some embodiments, the pocket extends only partially through the thermally conductive interposer.

One general aspect includes a wireless device that includes a monolithic microwave integrated circuit (MMIC) device, which may include: a MMIC die which may include: an active circuit layer, a first substrate material, and at least one conductive through-semiconductor via (TSV) extending completely through the first substrate material from a top side to a bottom side of the MMIC die. The MMIC device also includes a thermally conductive interposer that may include: a second substrate material different from the first substrate material and electrically insulating at an operating voltage of the MMIC die, at least one conductive via, pad, or trace in electrical contact with the at least one conductive TSV or the active circuit layer; and a pocket configured to receive the MMIC die.

Implementations may include one or more of the following features. In some embodiments, the first substrate material is silicon, gallium arsenide, or gallium nitride, or the second substrate material is silicon carbide, aluminum nitride, or diamond. In some embodiments, the at least one conductive via, pad, or trace may include a routing layer or redistribution layer or a conductive via extending completely through the second substrate material from a top side to a bottom side of the thermally conductive interposer.

This Summary is provided to introduce a selection of concepts in a simplified form that are further described below in the Detailed Description. This Summary is not intended to identify key features or essential features of the claimed subject matter, nor is it intended to limit the scope of the claimed subject matter. A more extensive presentation of features, details, utilities, and advantages of the MMIC with thermally conductive, pocketed interposer, as defined in the claims, is provided in the following written description of various embodiments of the disclosure and illustrated in the accompanying drawings.

### BRIEF DESCRIPTION OF THE DRAWINGS

Illustrative embodiments of the present disclosure will be described with reference to the accompanying drawings, of which:

FIG. 1 is a top side perspective view of an example thermally conductive, pocketed interposer, in accordance with at least one embodiment of the present disclosure.

FIG. 2 is a top side perspective view of an example MMIC that includes a MMIC die mounted to a thermally conductive, pocketed interposer, in accordance with at least one embodiment of the present disclosure.

FIG. 3 is a top side perspective view of an example MMIC that includes two stacked MMIC dies mounted to a thermally conductive, pocketed interposer, in accordance with at least one embodiment of the present disclosure.

FIG. 4 is a top side perspective view of an example MMIC that includes multiple MMIC dies mounted side-by-side to the pocket of a thermally conductive, pocketed interposer, in accordance with at least one embodiment of the present disclosure.

FIG. 5 is a top side perspective view of an example thermally conductive, pocketed interposer, in accordance with at least one embodiment of the present disclosure.

FIG. 6 is a top side perspective view of an example thermally conductive, pocketed interposer, in accordance with at least one embodiment of the present disclosure.

FIG. 7 is a top view of four different example configurations of thermally conductive, pocketed interposer and pocket, in accordance with at least one embodiment of the present disclosure.

FIG. 8 is a side cross-sectional view of an example MMIC that includes a MMIC die mounted to a thermally conductive, pocketed interposer, in accordance with at least one embodiment of the present disclosure.

FIG. 9 is a side cross-sectional view of an example MMIC that includes a MMIC die mounted to a thermally conductive, pocketed interposer, in accordance with at least one embodiment of the present disclosure.

FIG. 10 is a side cross-sectional view of an example MMIC that includes two MMIC dies mounted to a thermally conductive, pocketed interposer, and a thermally conductive, non-pocketed interposer, in accordance with at least one embodiment of the present disclosure.

FIG. 11 is a top side perspective view of an assembly process for a multi-layered, multi-die MMIC, in accordance with at least one embodiment of the present disclosure.

FIG. 12 is a schematic, diagrammatic view of an electronic device or a wireless device comprising a MMIC, in accordance with at least one embodiment of the present disclosure.

### DETAILED DESCRIPTION

In accordance with at least one embodiment of the present disclosure, a MMIC with thermally conductive, pocketed interposer is provided which provides the functionality of both a heat spreader and a pocketed interposer, while providing robust mechanical support for the MMIC die.

In some cases, a MMIC die may be mounted to a pocketed interposer that allows contacts on the top or bottom surface of the MMIC to be connected to other components (including other MMICs). Such interposers are typically made of silicon with gold or copper traces, and may be considered thermally insulating rather than thermally conductive, particularly at the high heat fluxes generated by a MMIC. Silicon is also a moderately robust material, although its thermal conductivity can be a limiting factor for some high-power applications. By contrast, the thermally conductive, pocketed interposer disclosed herein is made from an electrically insulating, thermally conductive material such as a wide-bandgap material. Example materials include but are not limited to silicon carbide (SiC), aluminum nitride, or diamond, all of which are mechanically much tougher than traditional interposer materials such as silicon. For example, the fracture toughness of SiC is 2.5-6.8 MPa m^{0.5}, the fracture toughness of aluminum nitride is 4.0-4.6 MPa m^{0.5}, and the fracture toughness of diamond is around 2.0 MPa m^{0.5}, whereas the fracture toughness of silicon (Si) is 0.7-1.3 MPa m^{0.5}. Similarly, the electrical resistance of SiC is between 10⁵ and 10⁷ ohm-cm, vs. 10³ to 104 ohm-cm. for undoped Si. For the purposes of this document, the term “electrically insulative” refers to any device or material that does not conduct electricity at the operating voltage of any devices, traces, etc. attached to the device or material.

In addition to an integrated thermal management solution, current and forward-looking applications are pointing to a need for integrating an interconnect solution to MMIC dies. Disclosed herein is a novel method of configuring and fabricating an “interconnect tabbed, pocketed MMIC” or “MMIC with thermally conductive, pocketed interposer”. With this innovation, a MMIC fabricator can supply a fine-pitch interconnect-enabled and thermally conductive MMIC that equipment manufacturers can then integrate into their products. Accordingly, this disclosure describes a method of integrating an advanced, fine-pitch interconnect-enabled and thermally conductive MMIC that supports not only higher levels of thermal performance than bare MMIC dies, but also provides a reliable mechanism of advanced interconnect for the customer's next-level assembly and integration.

Followed below are some of the key technical benefits of the solution outlined in this disclosure. The thermally conductive, pocketed interposer provides mechanical support to MIMIC dies, as they get thinner from the current 100 μm down to 50 μm, 25 μm and beyond. Mechanical handling is an important aspect of reducing yield loss, and as the thickness of MMIC dies continues to reduce, the thermally conductive, pocketed interposer provides mechanical robustness and additional benefits as are outlined herein. The thermally conductive interposer also allows a methodology for fan-out routing where required, thus supporting tighter interconnect pitch and smaller MMICs, without adversely impacting assembly considerations. As an added advantage, the customer can benefit from improved RF performance through the smaller die and shorter resultant signal paths. The thermally conductive, pocketed interposer also supports integration of multi-MMIC for non-packaged, bare-die sales. The tabbing process can support integration of two or more dies onto the thermally conductive, pocketed interposer, so as to deliver added functionality to unpackaged MMIC product offerings. This also shortens signal paths across multiple dies, by leveraging more advanced fabrication technologies for the thermally conductive, pocketed interposer.

The thermally conductive, pocketed interposer leverages wafer-fab like capabilities for line/space as well as via-definitions-which are usually superior compared to those from traditional laminates or other chip-carrier substrates. This capability allows for the MMICs to be routed more efficiently, thus reducing signal path in several scenarios, resulting in enhancements to the electrical/RF performance. This also enables superior, integrated thermal management solutions for bare MMIC die sales. When the MMIC with thermally conductive, pocketed interposer is properly designed and fabricated, its thermal performance can be significantly superior to that of the bare-die itself. The methodology described herein also enhances mechanical reliability performance through three-dimensional heterogeneous integration (3DHI). Use of advanced fab-like processes and technologies can make the MMIC with thermally conductive, pocketed interposer mechanically superior and more robust, thus increasing reliability.

These descriptions are provided for exemplary purposes only, and should not be considered to limit the scope of the MMIC with thermally conductive, pocketed interposer. Certain features may be added, removed, or modified without departing from the spirit of the claimed subject matter.

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

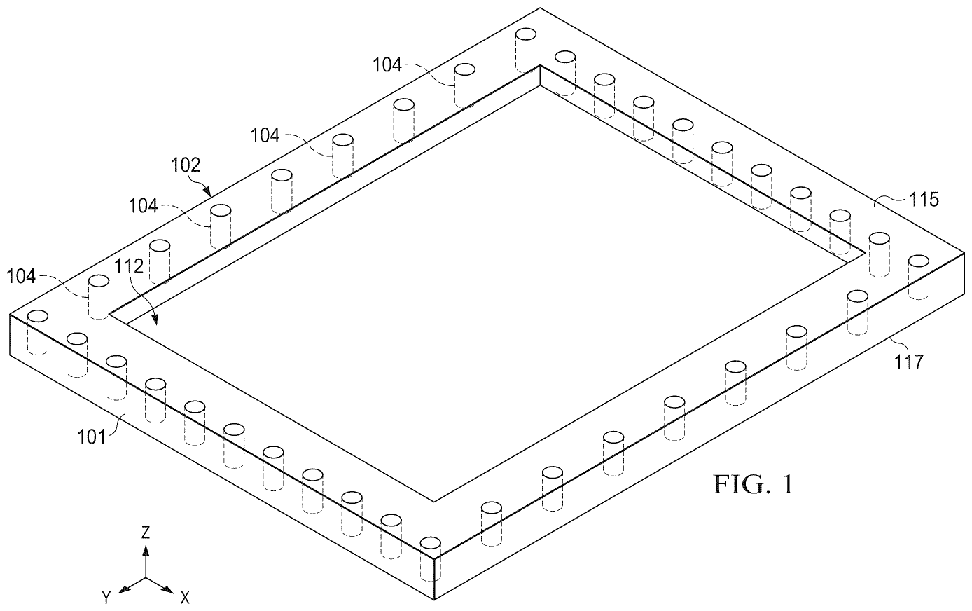

FIG. 1 is a top side perspective view of an example thermally conductive, pocketed interposer 102, in accordance with at least one embodiment of the present disclosure. In the example shown in FIG. 1, the thermally conductive, pocketed interposer 102 (also known as a tab, heat spreader, interconnect fabric, etc.) includes a substrate material 101 such as SiC that provides electrical insulation at the operating voltages of a MMIC, but also provides high thermal conductivity (e.g., 490 W/mK for SiC, vs. 140 W/mK for silicon—a 3.5× improvement) and high mechanical toughness (e.g., SiC offers 1.9-9.7 times as much fracture toughness as silicon). Additionally, the substrate material 101 crystalline structure may be configured in a manner that provides enhanced thermal conductivity. For example, dopants or impurities might be present affecting resistivity and/or thermal conductive properties of SiC alone. The concentration of the impurities would be present according to the desired properties. A pocketed interposer made from SiC thus offers capabilities not demonstrated by, nor contemplated for, traditional interposers made from silicon. Thus, the thermally conductive pocketed interposer offers clear advantages over existing interposers. For purposes of this document, “thermally conductive” shall mean a material or component with a thermal conductivity of at least 200 W/mK (e.g., between 200 and infinity W/mK).

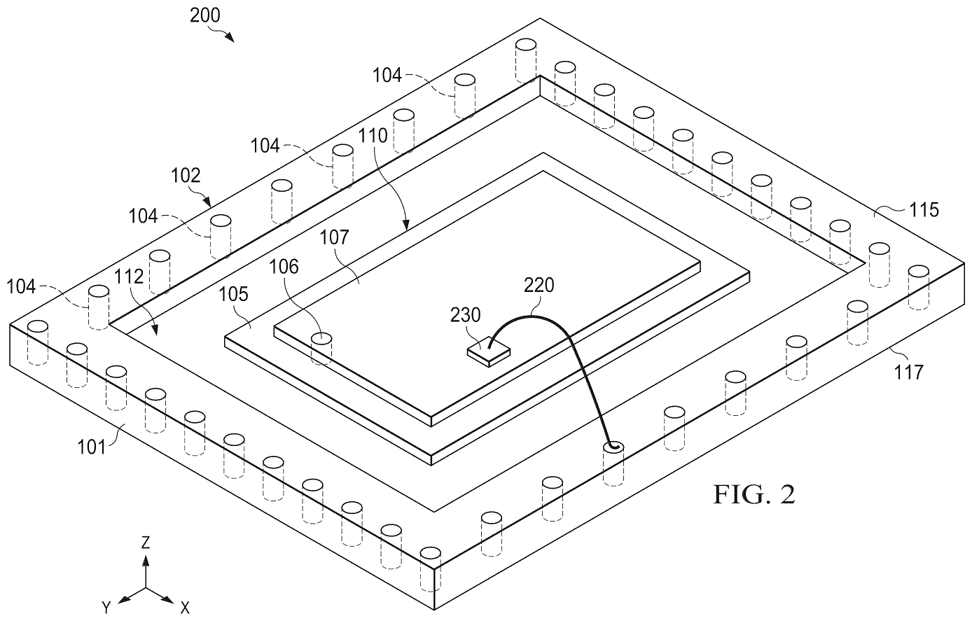

The thermally conductive, pocketed interposer 102 includes a pocket 112 for receiving a MMIC die. In some implementations, the pocket 112 may extend all the way through the substrate material 101, from the top surface 115 through to the bottom surface 117, thus forming an aperture or through-hole. In other implementations, the pocket 112 may extend from the top surface 115, but only partway through the substrate material 101, such that the bottom surface 117 remains intact, thus forming a recess or indentation. In either case, the pocket 112 is configured to receive a MMIC die, as shown below in FIGS. 2-4 and 8-11. In the example shown in FIG. 1, the pocket 112 extends approximately halfway through the substrate material 101.

In the example shown in FIG. 1, the thermally conductive interposer 102 also includes “hot” (e.g., electrically conductive) vias 104 that extend completely through the substrate material 101, from the top surface 115 to the bottom surface 117. In an example, the vias 104 are plated with an electrically conductive material such as copper but retain a hollow core. In other examples, the vias are entirely filled with the conductive material (e.g., copper. However, hollow vias may be preferable, as they allow conductive pillars or posts to be used to make contact between components placed on the top and bottom surfaces of the interposer 102, without the need for soldering or thermal bonding. In either case, the vias 104 allow devices or components on the top surface 115 to be in electrical communication (e.g., power, signal, ground, etc.) with devices or components on the bottom surface 117, while heat generated by these devices or components is dissipated by the thermally conductive substrate material 101. This interconnect capability is not present in, nor contemplated for, existing heat spreaders. Thus, the thermally conductive interposer offers clear advantages over existing heat spreaders.

Before continuing, it should be noted that the examples described above are provided for purposes of illustration, and are not intended to be limiting. Other devices and/or device configurations may be utilized to carry out the operations described herein.

FIG. 2 is a top side perspective view of an example MMIC 200 that includes a MMIC die 110 mounted to a thermally conductive, pocketed interposer 102, in accordance with at least one embodiment of the present disclosure. As shown above in FIG. 1, the thermally conductive interposer 102 includes vias 104 that extend completely through the interposer 102, from the top surface to the bottom surface. However, unlike FIG. 1, a MMIC die 110 has been attached in the pocket 112 of the thermally conductive interposer 102. The MMIC die 110 includes a semiconductor wafer or substrate 105, an active circuit plane 107, and an electrically conductive through-semiconductor via (TSV) 106 extending all the way through the active circuit plane 107 and the wafer or substrate 105. In the example shown in FIG. 2, the active circuit plane 107 is placed face-up within the pocket 112 in a wire-bond configuration, such that the active circuit plane 107 is flush with the top surface 115 of the thermally conductive, pocketed interposer 102. The MMIC die may for example be attached to the bottom and/or sides of the pocket 112 by an electrically insulative, thermally conductive adhesive such as Appli-Tec-5200-L conductive epoxy.

In the example shown in FIG. 2, a bond wire attaches a conductive pad 230 on the active circuit plane 107 to a conductive via 104 of the thermally conductive, pocketed interposer 102. Such bond wires may be used for fanout of the MMIC die 110.

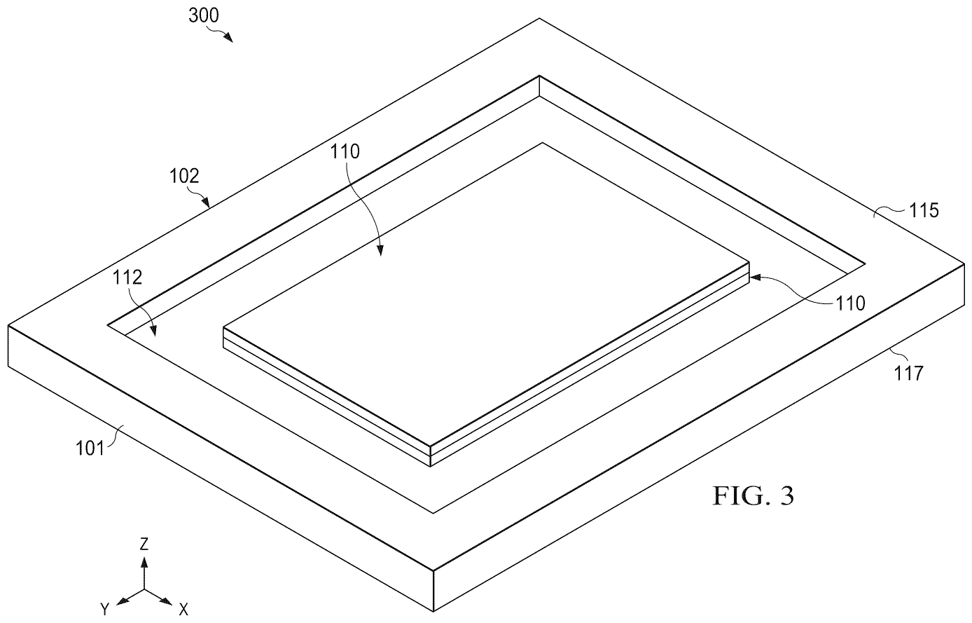

FIG. 3 is a top side perspective view of an example MMIC 300 that includes two stacked MMIC dies 110 mounted to a thermally conductive, pocketed interposer 102, in accordance with at least one embodiment of the present disclosure. The MMIC 300 is similar to the MMIC 200 of FIG. 2, except that a second MMIC die 110 has been stacked on top of the MMIC die 110 that is in contact with the pocket 112. Technology for stacking integrated circuit (IC) dies is described for example in U.S. Provisional Application No. 63/511,801, filed 3 Jul. 2023, entitled “Bare Flip-Chip Die Stack and the Fabrication Method and Tooling Thereof”, which is incorporated by reference as though fully set forth herein. Thermal management can be challenging for stacked MMIC dies. Attaching the stacked MMIC dies 110 to the thermally conductive, pocketed interposer 102 allows heat generated by the stacked MMIC dies 110 to be dissipated by the thermally conductive substrate material 101.

Although FIG. 3 shows the MMIC dies 110 without electrically conductive through-semiconductor vias, and the thermally conductive, pocketed interposer 102 is shown without electrically conductive vias, it is understood that such vias may be present in a variety of configurations as would occur to a person of ordinary skill in the art.

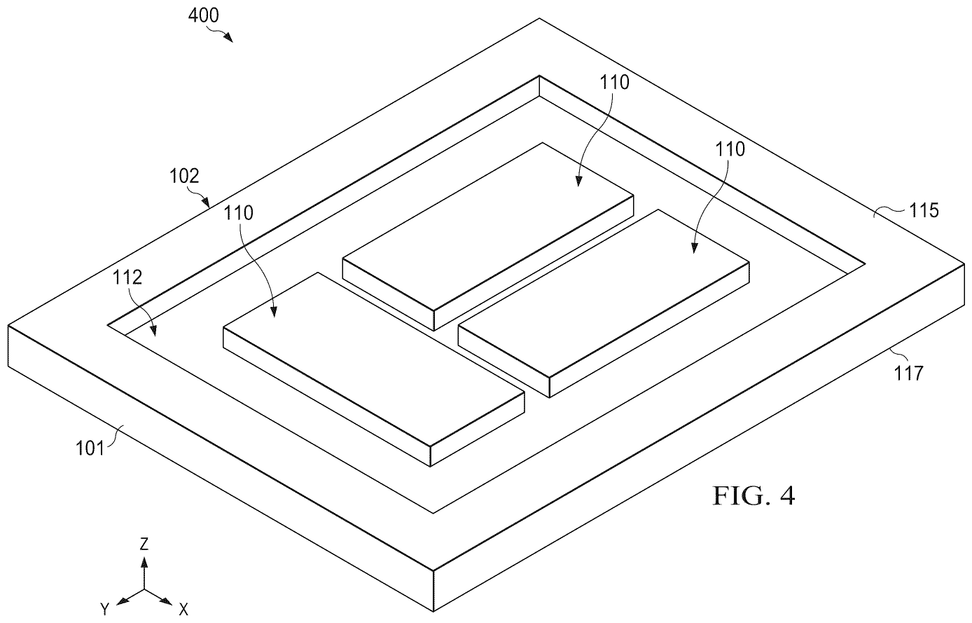

FIG. 4 is a top side perspective view of an example MMIC 400 that includes multiple MMIC dies 110 mounted side-by-side to the pocket 112 of a thermally conductive, pocketed interposer 102, in accordance with at least one embodiment of the present disclosure. The MMIC 400 is similar to the MMIC 300 of FIG. 3, except that the multiple dies 110 are placed side-by-side rather than being stacked. The MMICs may be placed face-up in a wire bond configuration, or face-down in a flip-chip configuration. Thus, interconnections between the MMIC dies 110 may be via wire bond, or via connections and pathways located within the thermally conductive, pocketed interposer 102, as will be readily understood by a person of ordinary skill in the art.

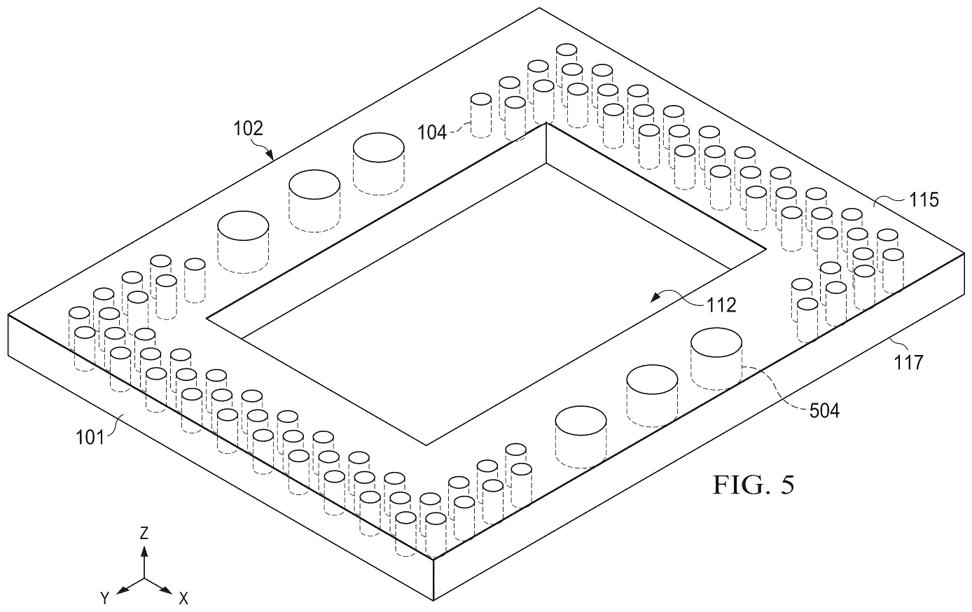

FIG. 5 is a top side perspective view of an example thermally conductive, pocketed interposer 102, in accordance with at least one embodiment of the present disclosure. In the example shown in FIG. 5, the thermally conductive, pocketed interposer 102 is configured for 3D heterogeneous integration (3DHI), and includes both small conductive vias 104 and large conductive vias 504. In an example, the small conductive vias 104 can be used to carry low-power digital signals from the top surface to the bottom surface of the thermally conductive, pocketed interposer 102, whereas the large vias 504, having more conductive material, can be used to carry higher-powered radio frequency (RF) signals. The pocket 112 extends all the way through the thermally conductive, pocketed interposer 102, from the top surface to the bottom surface.

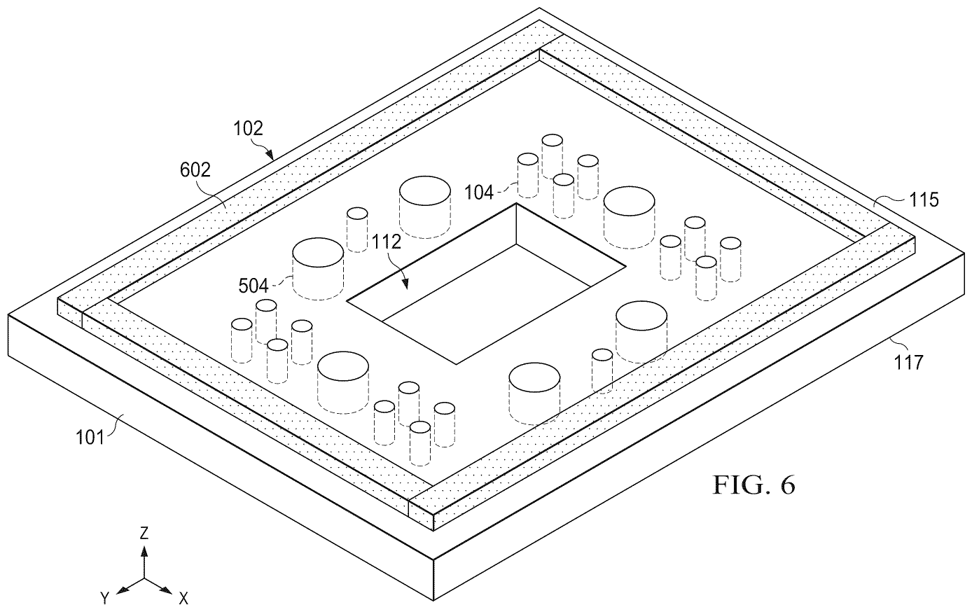

FIG. 6 is a top side perspective view of an example thermally conductive, pocketed interposer 102, in accordance with at least one embodiment of the present disclosure. In the example shown in FIG. 6, the thermally conductive, pocketed interposer 102 is configured for 3DHI, and includes both small conductive vias 104 and large conductive vias 504, as described above in FIG. 5, and may thus be useful for routing and/or fanout of both digital and RF signals. However, in the example shown in FIG. 6, the top surface of the thermally conductive, pocketed interposer 102 includes a conductive fence or perimeter 602. Depending on the implementation, the conductive fence or perimeter 602 may extend all the way around the perimeter of the thermally conductive, pocketed interposer 102 without apertures, or may include apertures, or may extend only partway around the perimeter of the thermally conductive, pocketed interposer 102. The conductive fence or perimeter 602 can be used for a variety of purposes, such as creating a metallic seal, electromagnetic interference (EMI) shield, proving an electrical ground connection (e.g., with TSVs connected to ground), and/or stacking additional MMIC dies or other thermally conductive interposers, whether pocketed or otherwise.

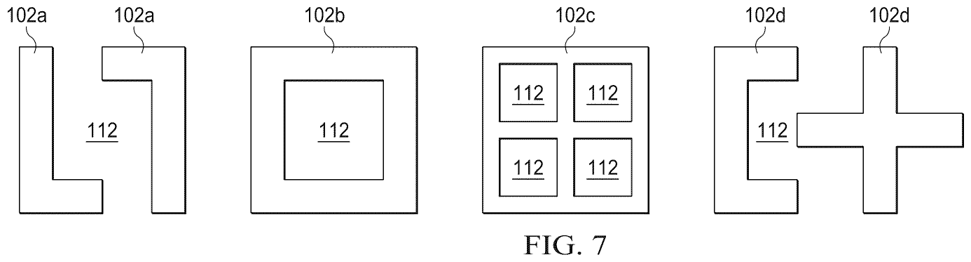

FIG. 7 is a top view of four different example configurations of thermally conductive, pocketed interposer 102 and pocket 112, in accordance with at least one embodiment of the present disclosure. In a first configuration, the thermally conductive, pocketed interposer includes two L-shaped pieces 102a which partially surround the pocket 112. In a second configuration 102b, the thermally conductive, pocketed interposer is rectangular, and completely surrounds a rectangular pocket 112. In a third configuration 102c, the thermally conductive, pocketed interposer is rectangular, and includes multiple pockets 112. In a fourth configuration, the thermally conductive, pocketed interposer includes multiple irregularly shaped pieces 102d that partially surround an irregular pocket 112. It is understood that the thermally conductive, pocketed interposer 102 and pocket 112 may assume myriad other configurations, both open and closed, while still falling within the scope of the present application.

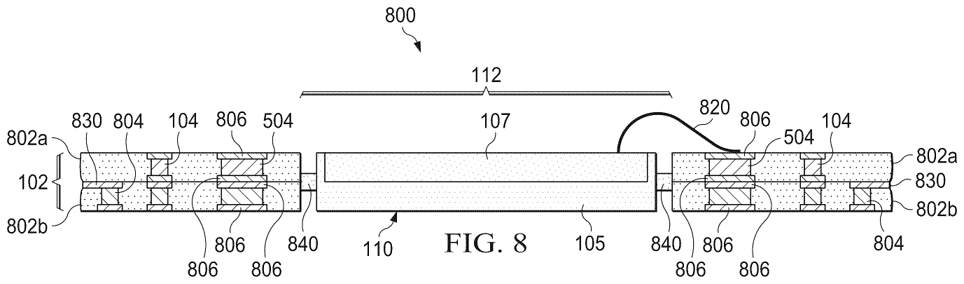

FIG. 8 is a side cross-sectional view of an example MMIC 800 that includes a MMIC die 110 mounted to a thermally conductive, pocketed interposer 102, in accordance with at least one embodiment of the present disclosure. In the example shown in FIG. 8, the thermally conductive, pocketed interposer 102 includes two layers 802a and 802b, which may be made of the same robust, thermally conductive, electrically insulative material (e.g., SiC), or may be made from different materials, depending on the implementation. The thermally conductive, pocketed interposer 102 also includes a pocket 112 that extends all the way through from its top surface to its bottom surface, as well as large vias 504 and small vias 104 that are each terminated at the top and bottom of each layer by contacts 806. The thermally conductive, pocketed interposer 102 also includes vias 804 that extend through only the bottom layer 802b, and terminate at a redistribution layer 830 located at the boundary between the top layer 802a and the bottom layer 802b. It is understood that the thermally conductive, pocketed interposer 102 may comprise three or more layers of a material such as SiC, wherein each layer may include any number of vias 104 or 504, contacts 806, and/or redistribution layers 830, whether connected other layers or not.

In the example shown in FIG. 8, the MMIC die is mounted face-up (e.g., in a wire-bond configuration within the pocket by a thermally conductive, electrically insulative adhesive 840, and is electrically connected to a contact 806 and conductive via 504 by a bond wire 820.

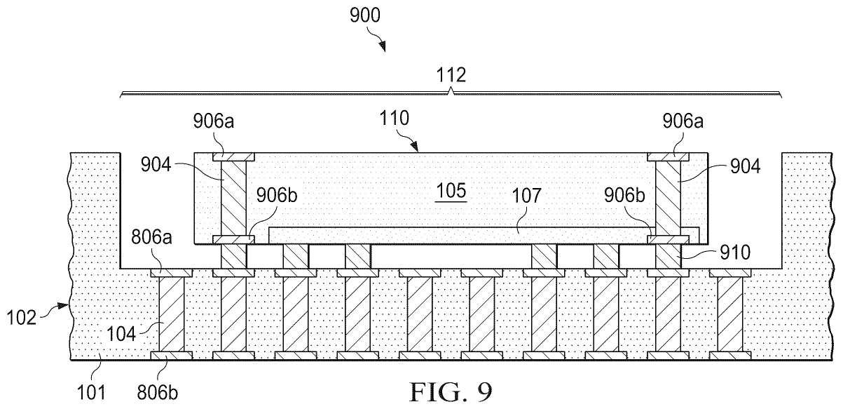

FIG. 9 is a side cross-sectional view of an example MMIC 900 that includes a MMIC die 110 mounted to a thermally conductive, pocketed interposer 102, in accordance with at least one embodiment of the present disclosure. In the example shown in FIG. 8, the thermally conductive, pocketed interposer 102 includes a pocket 112 extending roughly halfway through the substrate material 101. Mounted face-down (e.g., in flip-chip configuration) is a MMIC die 110.

The thermally conductive, pocketed interposer 102 includes electrically conductive vias 104 terminated by contacts 806a on the upper surface and contacts 806b on the lower surface. The MMIC die 110 includes through-semiconductor vias (TSVs) 904 terminated by contacts 906a on the upper surface and contacts 906b on the lower surface. At least some of the contacts 906b are connected by conductive connections 910 (e.g., posts, pillars, solder bumps, etc.) to contacts 806a on the thermally conductive, pocketed interposer 102, thus forming an electrical connection between contacts 906a on the upper surface of the MMIC die and contacts 806b on the lower surface of the thermally conductive, pocketed interposer 102.

Similarly, conductive connections 910 form electrical connections between the active circuit layer 107 of the MMIC die 110 and at least some of the contacts 806a on the upper side of the thermally conductive, pocketed interposer 102 (e.g., on the floor of the pocket).

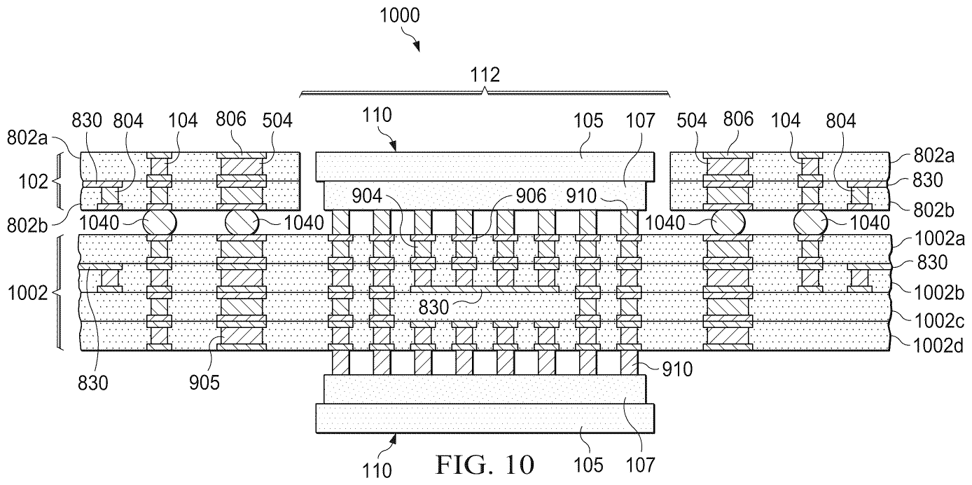

FIG. 10 is a side cross-sectional view of an example MMIC 1000 that includes two MMIC dies 110 mounted to a thermally conductive, pocketed interposer 102, and a thermally conductive, non-pocketed interposer 1002, in accordance with at least one embodiment of the present disclosure.

In the example shown in FIG. 10, the top MMIC die 110 is mounted face-down (e.g., in flip-chip configuration) within the pocket 112 of a thermally conductive, pocketed interposer 102. Like the thermally conductive, pocketed interposer 102 of FIG. 9, the thermally conductive, pocketed interposer 102 of FIG. 10 includes large vias 504, small vias 104, partial vias 804, and redistribution layers 830. The active circuit layer 107 of the top MMIC die is electrically connected to contacts 906 and vias 904 in the thermally conductive, non-pocketed interposer 1002 by electrically conductive connectors 910 (e.g., pillars, posts, solder bumps, etc.).

The thermally conductive, non-pocketed interposer 1002 comprises four layers, 1002a, 1002b, 1002c, and 1002d, and includes large vias 905, small vias 904, and partial vias 804, terminated by contacts 906. Both the thermally conductive, non-pocketed interposer 1002 and the thermally conductive, pocketed interposer 102 include redistribution layers (RDLs) 830. Other numbers of layers may be used instead or in addition, to route signals, power, and ground from one point to another.

The RDLs 830 are configured to redirect electrical power, signal, and/or ground from one pad or contact (or set of pads or contacts) 906 to another pad or contact (or set of pads or contacts) 906. This arrangement maximizes the flexibility of the MMIC 1000 for integration with other components, devices, or systems. Each RDL 830 can include edge conductors, internal conductors, and/or routing layers, separated by insulative regions. Each routing layer may include one or a multitude of traces for connecting pads 906 with other pads 906, or with internal conductors or edge conductors, as will be familiar to a person of ordinary skill in the art. Depending on the implementation, the RDLs may be manufactured as layers within, or on the surface of, the thermally conductive, pocketed interposer 102 or the thermally conductive, non-pocketed interposer 1002, or may be bonded (e.g., thermally or adhesively bonded) to either of these. The RDLs may be fabricated from the same materials as the thermally conductive, pocketed interposer 102 (e.g., SiC with copper-plated vias and pads), or may be made of different materials (e.g., Si, GaAs, or GaAn, with gold traces and pads).

At least some contacts 906 on the thermally conductive, pocketed interposer 102 are connected to contacts 906 on the thermally conductive, non-pocketed interposer 1002 by means of solder bumps 1040. Depending on the implementation, the thickness of the pads or contacts 906 can be as small as sub-micron dimensions, where the bonding is established by leveraging techniques such as thermos-compression bonding (TCB) and its variants or reflow based technologies, where a suitably thick layer of solder material-such as tin (Sn), tin-silver (SnAg) or other suitable metallurgy is leveraged.

The active circuit layer 107 of the lower MMIC 110 is electrically and mechanically connected to at least some contacts 906 of the thermally conductive, non-pocketed interposer 1002 by means of electrically conductive connectors (e.g., pillars, posts, solder bumps, etc.)

A person of ordinary skill in the art will appreciate that myriad combinations of the features shown in FIG. 10 may be employed to route signals, power, or ground from any point within the MMIC 1000 to any other point within the MMIC 1000, and that some contacts or pads 906 can be used as bonding sites for bond wires, to connect the MMIC 1000 to external components, devices, or systems. Combinations of the features shown in FIG. 10 can also be used to connect an arbitrary number of MMIC dies to one another in a single, thermally conductive, multi-die MMIC.

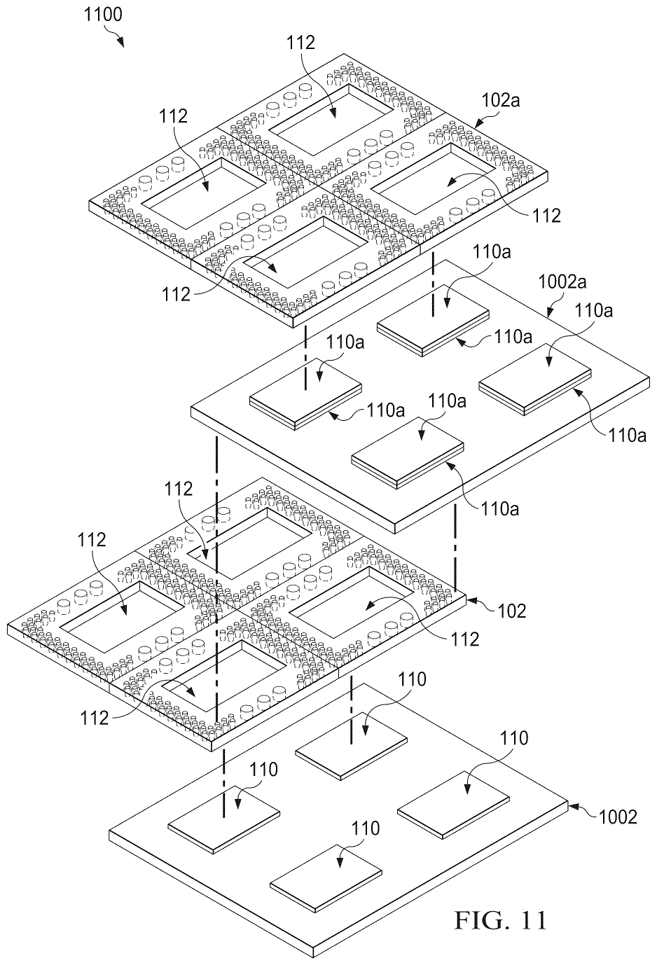

FIG. 11 is a top side perspective view of an assembly process for a multi-layered, multi-die MMIC 1100, in accordance with at least one embodiment of the present disclosure. In the example shown in FIG. 11, a thermally conductive, non-pocketed interposer 1002 has four MMIC dies 110 mounted to it. A thermally conductive, pocketed interposer 102, having four pockets 112, is attached to the thermally conductive, non-pocketed interposer 1002 such that the MMIC dies 110 fit within the pockets 112. A second thermally conductive, non-pocketed interposer 1002a is then stacked on top of the thermally conductive, pocketed interposer 102, with four stacks of two MMIC dies 110a attached to the second thermally conductive, non-pocketed interposer 1002a. A second thermally conductive, pocketed interposer 102a is then stacked on top of the second thermally conductive, non-pocketed interposer 1002a, such that its pockets 112 are aligned with the stacked MMIC dies 110a.

A person of ordinary skill in the art will appreciate that the elements shown in FIG. 11, or similar components that perform the same function using different form factors, can be combined in myriad ways to produce MMICs with an arbitrary number of dies and/or layers.

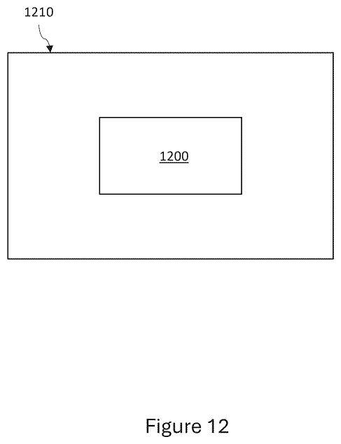

FIG. 12 is a schematic, diagrammatic view of an electronic device or a wireless device 1210 comprising a MMIC 1200, in accordance with at least one embodiment of the present disclosure. In some implementations, the electronic device or wireless device 1210 may include, for example, but not limited to, a computer, a cellular device, a satellite communication device, a wi-fi device, a radar, a global position system device, or any wireless device. In one or more embodiments, the MMIC 1200 may include a MMIC die mounted to a thermally conductive, pocketed interposer, such as MMIC 200 of FIG. 2, MMIC 300 of FIG. 3, MMIC 400 of FIG. 4, MMIC 800 of FIG. 8, MMIC 900 of FIG. 9, MMIC 1000 of FIG. 10, MMIC 1100 of FIG. 11, or other MMIC comprising an MMIC die mounted to a thermally conductive, pocketed interposer. The MMIC 1200 may implement any RF component used in wireless applications, as an example, such as one or more RF power amplifiers or in a radar or radar systems; and the MMIC 1200 may be coupled to other circuitry for implementing a wireless application.

Key elements of this disclosure include at least one MMIC die that has at least one through-semiconductor via (TSV) that is attached to a thermally conductive, pocketed interposer which includes at least one conductive via, conductive pad, and/or conductive trace. A plurality of any or all of these features-such as multiple TSVs, multiple dies, multiple vias, or multiple traces or routing layers within the thermally conductive pocketed or non-pocketed interposer(s) (as may be realized leveraging redistribution layers—RDL—or otherwise) expressly falls within the scope of the present disclosure.

Accordingly, it can be seen that the MMIC with thermally conductive, pocketed interposer advantageously provides heat dissipation, electrical insulation, and mechanical support that is superior to existing interposers, while providing an interconnectivity capability that does not exist in current heat spreaders.

A number of variations are possible on the examples and embodiments described above. For example, circuitry may be present on both the top and bottom sides of one or more MMIC dies. The MMIC die may be a flip chip or wire bond design, or combinations thereof. More than two MMIC dies may be stacked or positioned on the thermally conductive, pocketed or non-pocketed interposer. The number of redistribution layers (RDLs) in or on the thermally conductive, pocketed or non-pocketed interposer can be 0, 1, 2, 3, 4, 5, or more. The MMIC die and/or thermally conductive, pocket or non-pocketed interposer may be made from different materials than those described herein, while still performing the functions described above. Other devices or components may be attached or bonded to pads/vias of the thermally conductive, pocketed or non-pocketed interposer, including but not limited to wires, conductive traces, resistors, inductors, or capacitors. Instead of or in addition to conductive vias, the thermally conductive, pocketed interposer could include conductive traces or interconnects its upper surface, lower surface, or one or more sides. Multiple thermally conductive interposers (whether pocketed or not) may be stacked, with or without other layers or components between them.

The logical units making up the embodiments of the technology described herein are referred to variously as objects, elements, components, modules, layers, etc. Furthermore, it should be understood that these may occur in any order, unless explicitly claimed otherwise or a specific order is inherently necessitated by the claim language.

All directional references e.g., upper, lower, inner, outer, upward, downward, left, right, lateral, front, back, top, bottom, above, below, vertical, horizontal, clockwise, counterclockwise, proximal, and distal are only used for identification purposes to aid the reader's understanding of the claimed subject matter, and do not create limitations, particularly as to the position, orientation, or use of the MMIC with thermally conductive, pocketed interposer. Connection references, e.g., attached, coupled, connected, joined, or “in communication with” are to be construed broadly and may include intermediate members between a collection of elements and relative movement between elements unless otherwise indicated. As such, connection references do not necessarily imply that two elements are directly connected and in fixed relation to each other. The term “or” shall be interpreted to mean “and/or” rather than “exclusive or.” The word “comprising” does not exclude other elements or steps, and the indefinite article “a” or “an” does not exclude a plurality. Unless otherwise noted in the claims, stated values shall be interpreted as illustrative only and shall not be taken to be limiting.

The above specification, examples and data provide a complete description of the structure and use of exemplary embodiments of the MMIC with thermally conductive, pocketed interposer as defined in the claims. Although various embodiments of the claimed subject matter have been described above with a certain degree of particularity, or with reference to one or more individual embodiments, those skilled in the art could make numerous alterations to the disclosed embodiments without departing from the spirit or scope of the claimed subject matter.

Still other embodiments are contemplated. It is intended that all matter contained in the above description and shown in the accompanying drawings shall be interpreted as illustrative only of particular embodiments and not limiting. Changes in detail or structure may be made without departing from the basic elements of the subject matter as defined in the following claims.

What is claimed is:

1. A monolithic microwave integrated circuit (MMIC) device, comprising:
a MMIC die comprising:
an active circuit layer;
a first substrate material;
at least one conductive through-semiconductor via (TSV) extending completely through the first substrate material from a top side to a bottom side of the MMIC die;
a thermally conductive interposer comprising:
a second substrate material different from the first substrate material and electrically insulating at an operating voltage of the MMIC die;
at least one conductive via, pad, or trace in electrical contact with the at least one conductive TSV or the active circuit layer; and
a pocket configured to receive the MMIC die.

2. The MMIC device of claim 1, wherein the first substrate material is silicon, gallium arsenide, or gallium nitride or the second substrate material is silicon carbide, aluminum nitride, or diamond.

3. The MMIC device of claim 1, further comprising an electrically conductive fence at least partially surrounding the pocket on a surface of the thermally conductive interposer.

4. The MMIC device of claim 1, wherein the second substrate material has a thermal conductivity of at least at least 200 W/mK or a fracture toughness of between 2.0 and 6.8 MPa m^{0.5}.

5. The MMIC device of claim 1, wherein the at least one conductive via, pad, or trace comprises a routing layer or redistribution layer or a conductive via extending completely through the second substrate material from a top side to a bottom side of the thermally conductive interposer.

6. The MMIC device of claim 1, wherein the pocket extends completely through the thermally conductive interposer from a top surface to a bottom surface.

7. The MMIC device of claim 1, wherein the pocket extends only partially through the thermally conductive interposer.

8. The MMIC device of claim 1, wherein the MMIC die is attached to the pocket by a thermally conductive adhesive.

9. A method for packaging a monolithic microwave integrated circuit (MMIC), the method comprising:
providing a MMIC die comprising:
an active circuit layer;
a first substrate material;
at least one conductive through-semiconductor via (TSV) extending completely through the first substrate material from a top side to a bottom side of the MMIC die;
providing a thermally conductive interposer comprising:
a second substrate material different from the first substrate material and electrically insulating at an operating voltage of the MMIC die;
at least one conductive via, pad, or trace; and
a pocket configured to receive the MMIC die.
bonding the MMIC die to the thermally conductive interposer such that the at least one conductive via, pad, or trace is in electrical contact with the at least one conductive TSV or the active circuit layer.

10. The method of claim 9, wherein the first substrate material is silicon, gallium arsenide, or gallium nitride or the second substrate material is silicon carbide, aluminum nitride, or diamond.

11. The method of claim 9, further comprising providing an electrically conductive fence at least partially surrounding the pocket on a surface of the thermally conductive interposer.

12. The method of claim 9, wherein the second substrate material has a thermal conductivity of at least at least 200 W/mK or the second substrate material has a fracture toughness of between 2.0 and 6.8 MPa m^{0.5}.

13. The method device of claim 9, wherein the at least one conductive via, pad, or trace comprises a routing layer or redistribution layer or a conductive via extending completely through the second substrate material from a top side to a bottom side of the thermally conductive interposer.

14. The method of claim 9, wherein the pocket extends completely through the thermally conductive interposer from a top surface to a bottom surface.

15. The method of claim 9, wherein the pocket extends only partially through the thermally conductive interposer.

16. The method of claim 11, wherein the MMIC die is attached to the pocket by a thermally conductive adhesive.

18. A wireless device comprising:
a monolithic microwave integrated circuit (MMIC) device, comprising:
a MMIC die comprising:
an active circuit layer;
a first substrate material;
at least one conductive through-semiconductor via (TSV) extending completely through the first substrate material from a top side to a bottom side of the MMIC die;
a thermally conductive interposer comprising:
a second substrate material different from the first substrate material and electrically insulating at an operating voltage of the MMIC die;
at least one conductive via, pad, or trace in electrical contact with the at least one conductive TSV or the active circuit layer; and
a pocket configured to receive the MMIC die.

19. The wireless device of claim 18, wherein the first substrate material is silicon, gallium arsenide, or gallium nitride or the second substrate material is silicon carbide, aluminum nitride, or diamond.

20. The wireless device of claim 18, wherein the at least one conductive via, pad, or trace comprises a routing layer or redistribution layer or a conductive via extending completely through the second substrate material from a top side to a bottom side of the thermally conductive interposer.
